(19) United States
(12) Patent Application Publication
(10) Pub. No.: US 2014/0187295 A1
(43) Pub. Date: Jul. 3, 2014

(54) Electronic Device Case Capable of Performing Multiple Functions

(71) Applicants: Mukesh Kumar, Warsaw, IN (US); Michael D. Leach, Warsaw, IN (US); Jason David Meridew, Warsaw, IN (US); Thomas Jude Mauch, South Bend, IN (US)

(72) Inventors: Mukesh Kumar, Warsaw, IN (US); Michael D. Leach, Warsaw, IN (US); Jason David Meridew, Warsaw, IN (US); Thomas Jude Mauch, South Bend, IN (US)

(21) Appl. No.: 14/105,081

(22) Filed: Dec. 12, 2013

Related U.S. Application Data
(60) Provisional application No. 61/748,503, filed on Jan. 3, 2013.

(51) Int. Cl. H05K 7/14

(52) U.S. Cl. CPC H05K 7/14
USPC 455/575.1; 361/807; 361/679.56; 361/679.4

(57) ABSTRACT

An embodiment of the invention comprises an electronic device case including a power source and circuit board. The circuit board may be connected to the buttons allowing the electronic device case to function as a standalone device. The electronic device case includes a dedicated power source allowing the utilization of the case as a standalone device regardless of whether the electronic device is housed within the case.

### CROSS-REFERENCE TO RELATED APPLICATIONS

This application claims the benefit of U.S. Provisional Application No. 61/748,503, filed on Jan. 3, 2013.

### FIELD

The present disclosure relates to an electronic device case including a power source configured to provide power to a circuit board capable of performing various functions.

### BACKGROUND

This section provides background information related to the present disclosure, which is not necessarily prior art.

Electronic devices, such as cellular phones and tablet computers are utilized in an ever-increasing manner. For example, people often replace their landlines in favor of carrying a cellular phone. In addition, the current population's need to be constantly in communication with others, along with the demands of business requiring the same, very often necessitates that individuals constantly carry their cellular phones with them.

As the cost of electronic devices has increased, the need for individuals to protect those same phones has increased as well. Consequently, individuals often protect their devices with cases. These cases protect the device by reducing impact received by the device in the event that the phone is dropped. In addition, for certain devices with bodies at least partially made of glass; a device case may prevent the glass from scratching as the device is carried in a purse or a pocket of an individual.

### SUMMARY

The present invention is directed to a case for an electronic device. The case for the device includes a backside and a sidewall. The sidewall extends from the backside. The sidewall defines a recess, and the recess is sized and configured to receive an electronic device. The case also includes a power source and a circuit connected to the power source. The circuit is capable of performing some type of function regardless of whether the electronic device is located within the recess.

In an embodiment, the case comprises a sidewall. The sidewall defines a recess sized and configured to receive an electronic device. The case also includes a backside connected to the sidewall. The backside includes a power source and a circuit modularly connected to the backside and electrically connected the power source. The circuit is configured to perform a function.

In an embodiment, the case comprises a sidewall. The sidewall defines a recess configured to receive an electronic device. The case also includes a backside connected to the sidewall. The case also includes a power source and a circuit at least partially located within the backside and electrically connected to the power source. In addition, the circuit wirelessly connects to the electronic device.

### DRAWINGS

The drawings described herein are for illustrative purposes only of selected embodiments and not all possible implementations, and are not intended to limit the scope of the present disclosure.

FIG. 1 is a perspective view of a case representing an embodiment of the present invention.

FIG. 2 is an underside perspective view of the embodiment of the electronic device case depicted in FIG. 1.

FIG. 3 is an underside perspective view of the embodiment of the electronic device case depicted in FIG. 1 with the cover removed.

FIG. 4 is a front perspective view of an embodiment of a device cover representing an embodiment of the present invention.

FIG. 5 is a rear perspective view of the embodiment of the device depicted in FIG. 4.

FIG. 6 is a front perspective view of a first circuit module capable of being utilized in embodiments of the invention.

FIG. 7 is a front perspective view of a second circuit module capable of being utilized in embodiments of the invention.

FIG. 8 is a rear perspective view of an embodiment of the device cover representing an embodiment of the present invention.

FIG. 9 is a rear perspective view of the embodiment of the invention depicted in FIG. 8.

FIG. 10 is a front perspective view of an embodiment of the device cover representing an embodiment of the present invention.

FIG. 11 is a rear perspective view of the embodiment of the invention depicted in FIG. 10.

FIG. 12 is a perspective view of a portion of the embodiment of the device cover depicted in FIG. 10.

Corresponding reference numerals indicate corresponding parts throughout the several views of the drawings.

### DETAILED DESCRIPTION

Example embodiments will now be described more fully with reference to the accompanying drawings.

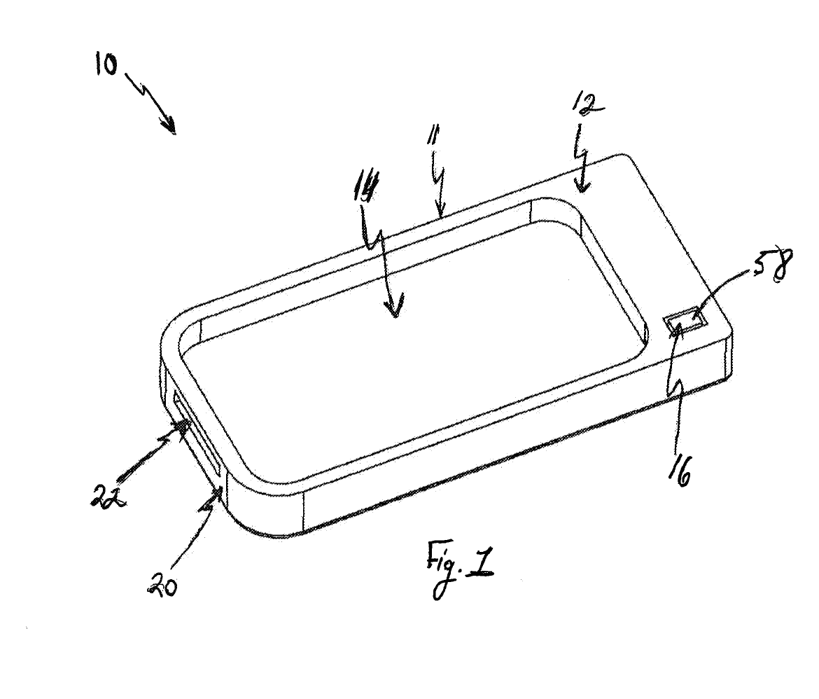

With initial reference to FIGS. 1-3, numeral 10 generally indicates an electronic device case representing an embodiment of the present invention, and accordingly, the device case 10 will be described as such. It should be noted that the electronic device case 10 need not be configured to receive just cell phones, but rather electronic device case 10 may be configured to receive any suitable electronic device such as a tablet computer in addition to the phone case. It should be noted that throughout this application, the phrase electronic device, phone and tablet are used interchangeably.

Referring still to FIGS. 1-3, in the depicted embodiment, the electronic device case 10 is a cellular phone case. In the depicted embodiment, electronic device case 10 includes a body 11 including a front face, indicated by numeral 12. Body 11 may be manufactured from any suitable material. In the depicted embodiment, front face 12 includes a phone receiving recess 14 and an optics opening 16. It should be understood by one with ordinary skill in the art that the phone receiving recess 14 may be shaped to receive any type of cell phone desired. For example, in embodiments wherein electronic device case 10 will be utilized in conjunction with an iPhone cellular phone manufactured by Apple Inc., phone receiving recess 14 may be configured with a generally rectangular shape corresponding to that of an iPhone.

Electronic device case 10 further includes a side wall indicated by numeral 20. Side wall 20 may include recesses, as exemplified in the depicted embodiment by recess 22, in order to allow access to ports located on the side of the cellular phone to be received within the phone receiving recess 14. As should be understood with one of ordinary skill in the art, the number, location and shape of the recesses 22, may vary to match the same number, location and shape of recesses in the cellular phone received in the phone receiving recess 14.

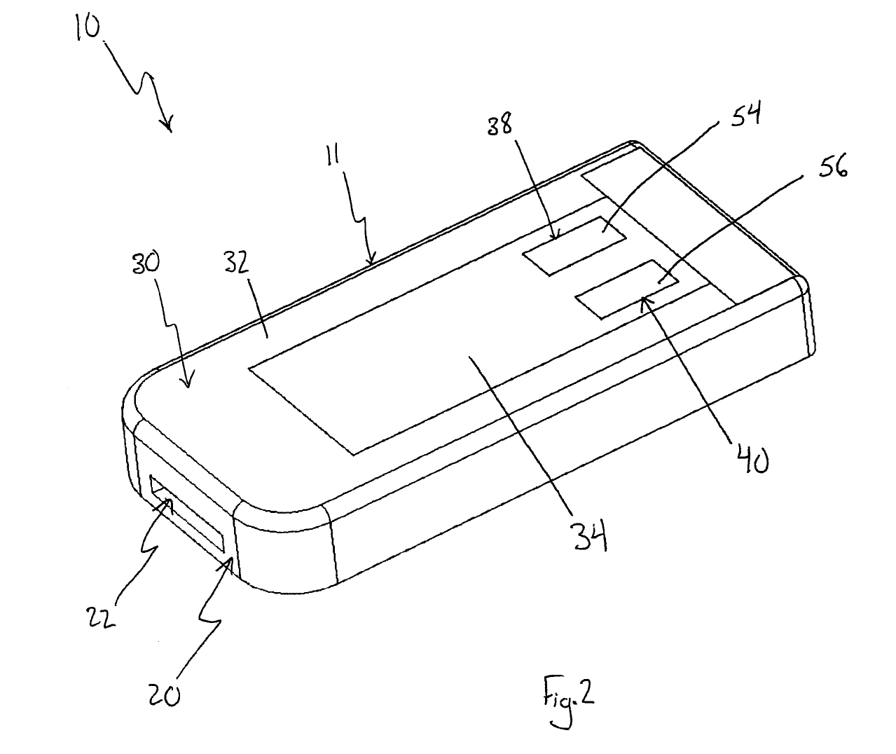

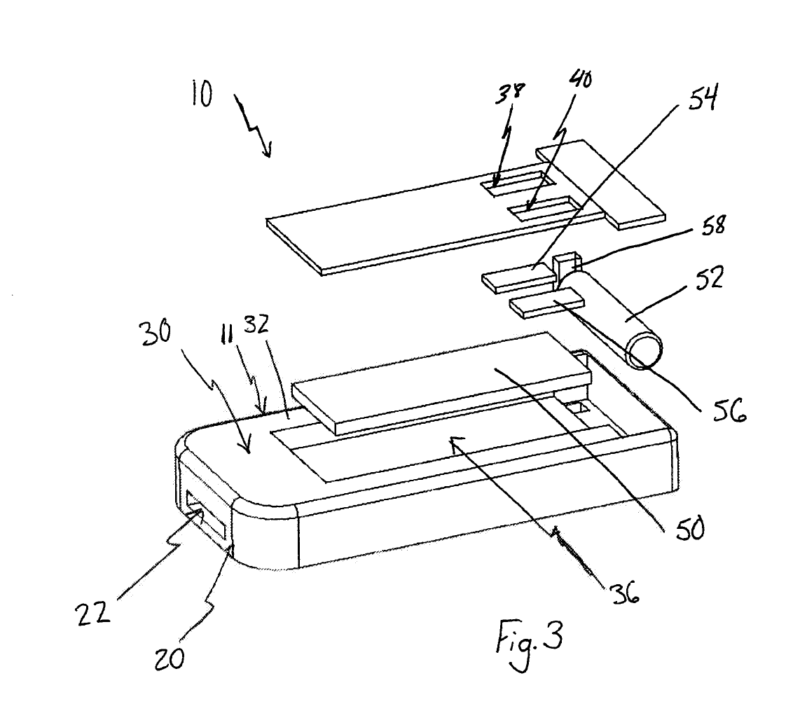

With reference now specifically to FIGS. 2 and 3, body 11 further includes a backside indicated by numeral 30. Backside 30 includes a back surface 32 and a cover 34. Furthermore, as shown specifically in FIG. 3, backside 30 further includes a recessed area 36.

With reference again to FIG. 2, backside 30 is substantially smooth, with the exposed surface of back surface 32 and cover 34 being substantially located in a single plane. Cover 34 may be held in a position relative to back surface 32 by any suitable mechanism, such as via a snap fit or with a locking screw, as would be understood by one with ordinary skill in the art. In the depicted embodiment, cover 34 includes a plurality of button receiving holes, indicated by numerals 38 and 40, respectively. As will be explained in greater detail below, holes 38, 40 may take any shape desired.

With reference to FIG. 3, electronic device case 10 further includes a circuit board 50, a power source 52, button 54, button 56 and optics 58 all generally positioned within the recessed area 36. Circuit board 50 may be of any suitable type of circuit board configured to achieve the desired function of electronic device case 10. In the depicted embodiment, electronic device case 10 is configured to also function as a computer mouse, in addition to protecting a cell phone received therein. The function of circuit board 50 in the depicted embodiment will be explained in greater detail below.

Power source 52 may be any type of power source sufficient capable of powering the functions of the cellular phone cover in accordance with the present invention. For example, power source 52 may be a disposable battery of the type AA, AAA, C, D, 9-volt or a button type or disc type battery typically utilized in watches and the like. In embodiments of the invention, however, power source 52 may be a rechargeable lithium ion type battery capable of being recharged while within the recessed area 36 or capable of being removed from the recessed area 36 for recharging.

Buttons 54, 56 may be connected to circuit board 50 in a known manner. In addition, buttons 54, 56 may have any shape desired, however, the shape of buttons 54, 56 and holes 38, 40 should be complementary thereby allowing buttons 54, 56 to be located within holes 38, 40 respectively.

With reference to FIGS. 1 through 3, in the depicted embodiment optics 58 are substantially located within recessed area 36. A portion of optics 58 is located within optics opening 16. It is desirable in the depicted embodiment that the portion of optics 58 located within optics opening 16 be substantially flush with front face 12. Optics 58 may be retained in a desired position via any suitable mechanism known in the art.

When assembled as depicted in FIGS. 1 through 3, the depicted embodiment of electronic device case 10 will protect a cell phone from damage, but will also have the ability to function as a mouse for interaction with a computer. For example, the buttons 54, 56 will allow a user to “click” in a manner consistent with a standard mouse, and circuit board 50 will translate and communicate that clicking to a computer wirelessly connected to electronic device case 10. It should be noted that electronic device case 10 might be wirelessly connected to a computer via any standard protocol, such as Bluetooth. In a similar manner, optics 58 may read movement of the electronic device case 10 across a flat surface, such as the top surface of the table or desk and communicate said movement to the circuit board 50. Circuit board 50 may then communicate the read movement to a joined computer in order to move the mouse pointer shown on the screen of the computer in a manner that corresponds to the movement of the electronic device case 10 across a surface. In this manner, the electronic device case 10 may function as a mouse. It should be noted, however, that the wireless connection of the electronic device case 10 and the corresponding computer may utilize the Bluetooth connectivity of the cellular phone protected by electronic device case 10, where available, but embodiments of electronic device case 10 may rely upon the circuit board 50 in its entirety for wireless connection with the computer.

In other embodiments of the invention, the circuit board 50 may be configured to function in alternative manners. For example, the circuit board 50 may be connected to a radio frequency transmitter and receiver. This would allow the electronic device case 10 to function as a garage door opener when both buttons 54, 56 are depressed at the same time, thereby sending a signal to a garage door coupled to the electronic device case 10 and causing the garage door opener to open or close a garage door in a standard manner. In this manner, the electronic device case 10 may function as both a mouse and a garage door opener. In embodiments, a single button may be utilized in electronic device case 10, and circuit board 50 may be configured to send out signals capable of being received by a garage door opener. In embodiments, the radio frequency transmitter and receiver may be allow electronic device case 10 to interact with any radio frequency devices, such as car doors, home doors or home alarms.

Still, in embodiments of the invention, electronic device case 10 may have circuit board 50 configured to function as a glucose monitor or laser pointer, and electronic device case 10 may include corresponding features of such devices. In addition, in embodiments, electronic device case 10 may include a recess or pocket sized and configured to receive a USB thumb drive. The USB thumb drive may be separate from electronic device case 10 or, in embodiments, may be integral to the electronic device case 10.

In embodiments of the invention, the electronic device case 10 includes a power source 52 allowing the electronic device case 10 to function without a cellular phone being contained therein. Accordingly, the electronic device case 10 need not rely on the power of a cellular phone protected therein, thereby prolonging the usable life of the cellular phone without requiring a recharge of the battery of the cellular phone. In addition, the battery of the cellular phone protected by the electronic device case 10 need not have any charge for the electronic device case 10 to function. In addition, the device case 10 functions without the electronic device being present within the recess 14.

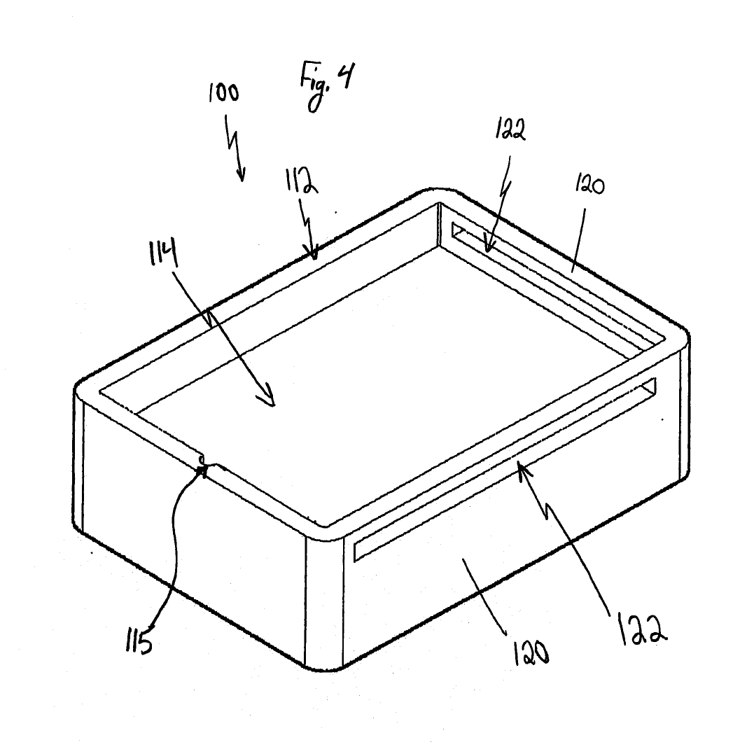

FIG. 4 depicts a device case generally indicated by numeral 100. Device case 100 may be sized and configured to be utilized with any suitable electronic device, such as an iPhone, iPad or iPad mini, all of which are manufactured and sold by Apple Inc. In the depicted embodiment, case 100 includes a body indicated by numeral 111 comprising a front face 112 and receiving recess 114. In the depicted embodiment, front face 112 includes an indentation 115. Receiving recess 114 is sized and configured to receive any suitable electronic device such as those described above or any similar cellular phone device or tablet computing device. Indentation 115 may be sized and configured to allow a user to gain leverage over the device (not shown) located within receiving recess 114 in order to remove the device from the case 100.

Body 111 further includes a plurality of sidewalls each indicated by 120. In the depicted embodiment, body 111 includes four sidewalls 120. Each sidewall 120 may include at least one recess 122. Each recess 122 may be sized and configured to allow connection of any cord to the device located within receiving recess 114, such as, for example, power cords, speaker cords, USB connecting cords or any similar cord. In addition, recess 122 may be configured to allow a user to access buttons or switches located on the device located within receiving recess 114.

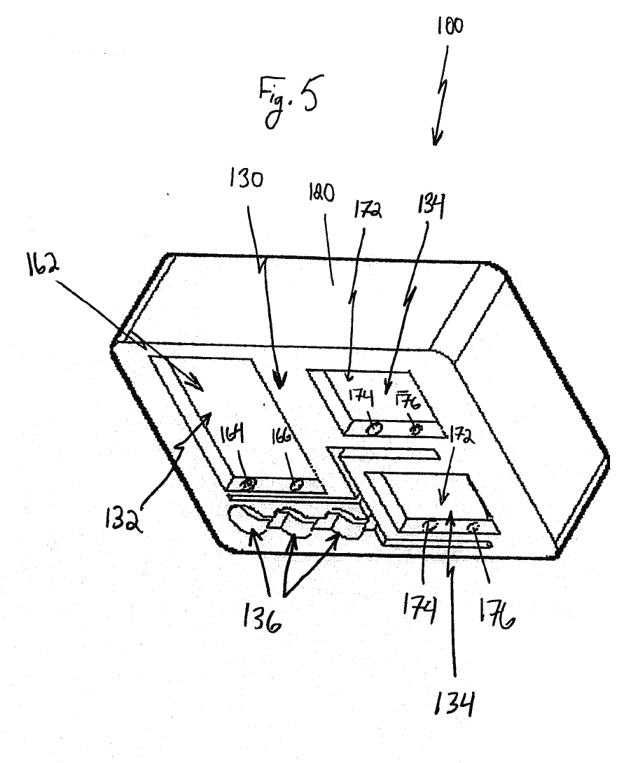

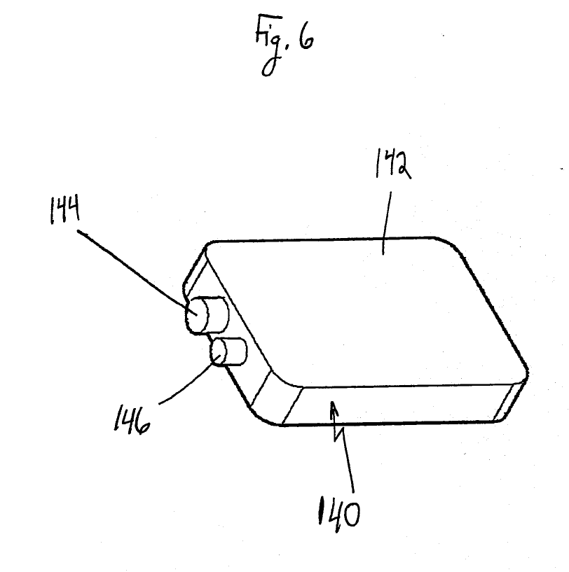

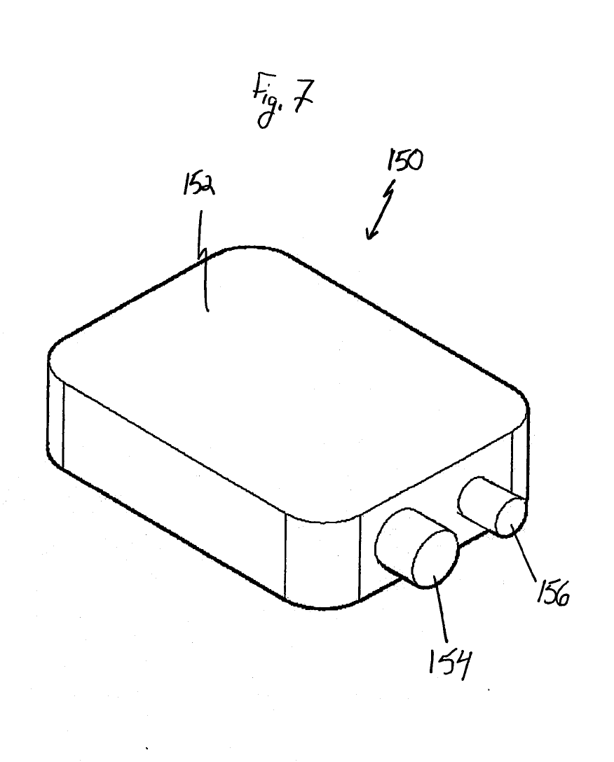

FIG. 5 depicts a rear perspective view of the device case 100 shown in FIG. 4. The embodiment depicted in FIG. 5 includes a backside 130. In the depicted embodiment, backside 130 includes a plurality of cavities, each type generally indicated by numerals 132, 134 and 136. In the embodiment depicted in FIG. 5, cavity 132 is configured to receive a first circuit module, indicated by numeral 140 in FIG. 6, and cavities 134 is configured to receive a second circuit module, indicated by numeral 150 in FIG. 7. Cavities 136 may be configured to receive any conventional battery. For example, cavities 136 may be configured for each to receive a standard button or disc type of battery, such as CR2032 for example. In other embodiments, the number of cavities 136 and size of cavities 136 may be configured to receive any standard type of battery “AA”, “AAA”, “C”, “D” or nine volt battery, of both the rechargeable and the disposable variety.

With reference now to FIG. 6, first circuit module 140 includes a housing 142, a first circuit connector 144 and a second circuit connector 146. Housing 142 is configured with a hollow area (not shown) configured to receive a circuit board (not shown) capable of performing a variety of functions. Housing 142 may be manufactured from any suitable material, and in general, any suitable insulated material such as plastic. First circuit connector 144 and second circuit connector 146 are configured to allow interaction of the circuit board housed within housing 142 and case 100 when the first circuit module 140 is inserted into cavity 132. In the depicted embodiment, first circuit connector 144 and second circuit connector 146 are of similar shape but differ in size. In other embodiments, the connectors 144, 146 may be of similar size but may differ in shape. In other embodiments, the connectors 144, 146 may differ in both size and shape.

With reference now to FIG. 7, second circuit module 150 includes a housing 152, a first circuit connector 154 and a second circuit connector 156. Housing 152 is configured with a hollow area (not shown) configured to receive a circuit board (not shown) capable of performing a variety of functions. Housing 152 may be manufactured from any suitable material, and in general, any suitable insulated material such as plastic. First circuit connector 154 and second circuit connector 156 are configured to allow interaction of the circuit board housed within housing 152 and case 100 when the second circuit module 150 is inserted into cavity 134. In the depicted embodiment, first circuit connector 154 and second circuit connector 156 are of similar shape but differ in size. In other embodiments, the connectors 154, 156 may be of similar size but may differ in shape. In other embodiments, the connectors 154, 156 may differ in both size and shape.

Referring again to FIG. 5, in the depicted embodiment of case 100, the cavities 132 and 134 have similar configurations differing only in size. For example, cavity 132 includes a circuit module receiving area, generally indicated by numeral 162 and module connector receiving apertures 164, 166. In the depicted embodiment, apertures 164 and 166 are sized and configured to receive connectors 144, 146. Apertures 164, 166 differ in size and shape in order to match the size and shape of the connectors 144, 146. Similarly, cavity 134 includes a circuit module receiving area, generally indicated by numeral 172 and module connector receiving apertures 174, 176. In the depicted embodiment, apertures 174, 176 are sized and configured to receive connectors 154, 156. Apertures 174, 176 differ in size and shape in order to match the size and shape of the connectors 154, 156.

In the depicted embodiment, the case 100 may include a variety of circuit boards (not shown) configured to interact with first circuit module 140 and second circuit module 150. The interaction of the circuit boards and circuit modules 140, 150 allow the device case to perform a variety of functions, such as, for example, a computer mouse, USB reader, USB Drive, pedometer, breathalyzer, accelerometer, a transmitter and receiver, a remote control, AM/FM radio, garage door opener, laser pointer, laser leveler, laser distance measurer, house lighting remote, LCD display, voice memo recorder, car key fab, car remote starter, flashlight, flexible key board, any type of blue tooth device, a hobby board (such as Arduino, Raspberry Pi, BeagleBone, or any similar type board), Blood Chemistry (such as a glucometer), speaker (both as a single mono speaker or a pair of speakers for stereo) and connection ports (such as USB, HDMI, component video, or similar connection). Moreover, due to the inclusion of the batteries within cavities 136, the case 100 may utilize the functions of the circuit modules 140, 150 without the presence of an electronic device in the receiving recess 114. For example, a user may desire to utilize the case 100 as a garage door opener. Accordingly, a circuit module 140 may be inserted into cavity 132. In addition, circuit module 140 may include an actuation button (not shown) and signal transmitting technology (not shown) allowing the circuit module 140 to utilize power from the batteries within cavities 137 upon actuation of the button in order to transmit a signal to a user's garage door opener instructing said opener to open the user's garage.

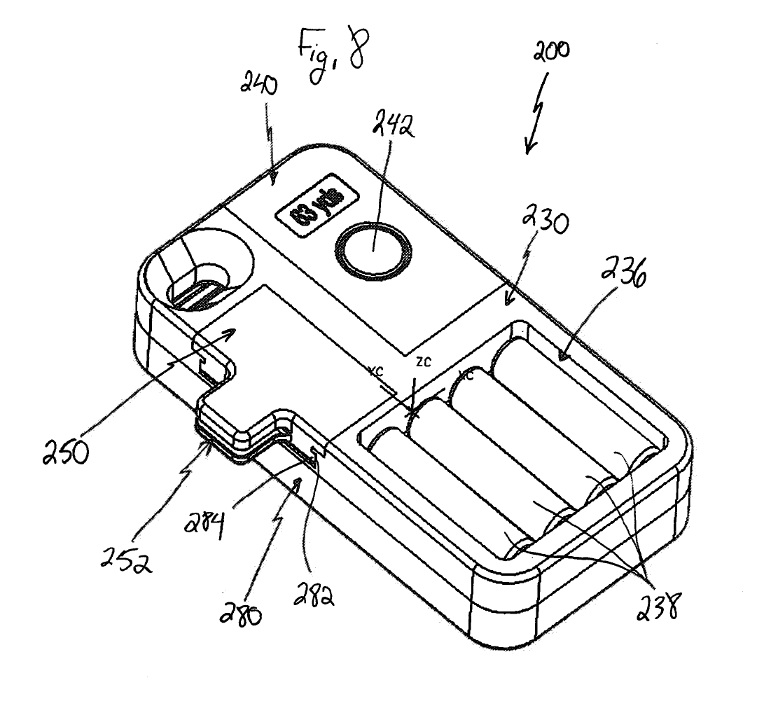

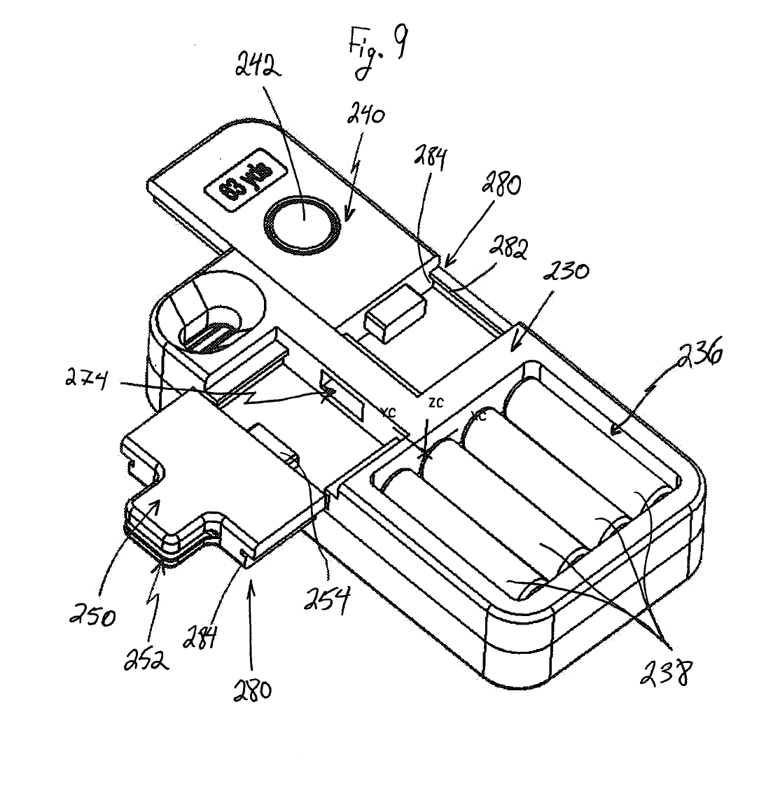

Referring now to FIGS. 8 and 9, another embodiment of a case representing the present invention is generally indicated by numeral 200. The front side of the case 200 is similar to the fronts of the previously described embodiments. The case 200 includes a backside 230 and a cavity 236 including a plurality of batteries 238. In the depicted embodiment, batteries 238 are “AAA” batteries, but may be any known type of battery. In the depicted embodiment, case 200 includes a first circuit module 240 and a second circuit module 250. In a manner similar to that described above, the circuit modules 240, 250 include circuit boards (not shown) and any known mechanism for actuating the circuit board, such as a button or switch 242. In the depicted embodiment, module 240 includes a connector 244 and module 250 includes a connector 254. The connectors 244 and 254 connect the modules 240, 250 with the case 200. For example, when module 250 is inserted into case 200, connector 254 is located within case opening 274. The connection between connector 254 and opening 274 allows the module 250 to access circuits (not shown) and batteries 238 of the case 200. In the depicted embodiment, module 240 includes a digital display or readout indicated by numeral 281. Display 281 is able to display information to the user as necessary and corresponding to the function of module 240 plugged into the case 200.

Referring still to FIGS. 8 and 9, case 200 and includes dove tail connections generally indicated by numeral 280. In the depicted embodiment, each dovetail connection 280 allows the backside 230 to be connected to modules 240, 250. Each dovetail connection 280 includes a first portion 282 and a second portion 284. In the depicted embodiment, first portion 282 is a male portion and second portion 284 is a complementary female portion. The inclusion of dovetail connections 280 allows each of the modules 240, 250 to be slidably connected to backside 230.

It should be noted that in the depicted embodiment, the modules 240, 250 form a portion of sidewall 220. Accordingly, modules 240, 250 may include functional portions that extend beyond the sidewall 220. For example, module 250 may include a slot 252 that allows the module 250 to read a credit card (not shown). Upon reading a credit card, the module 250 may transmit the information obtained in reading the credit card to the device housed within the case 200 via Bluetooth, near field communication, WiFi or any similar communication protocol. The phone may then utilize a software application residing on the phone to verify such information and process said payment information in a standard manner.

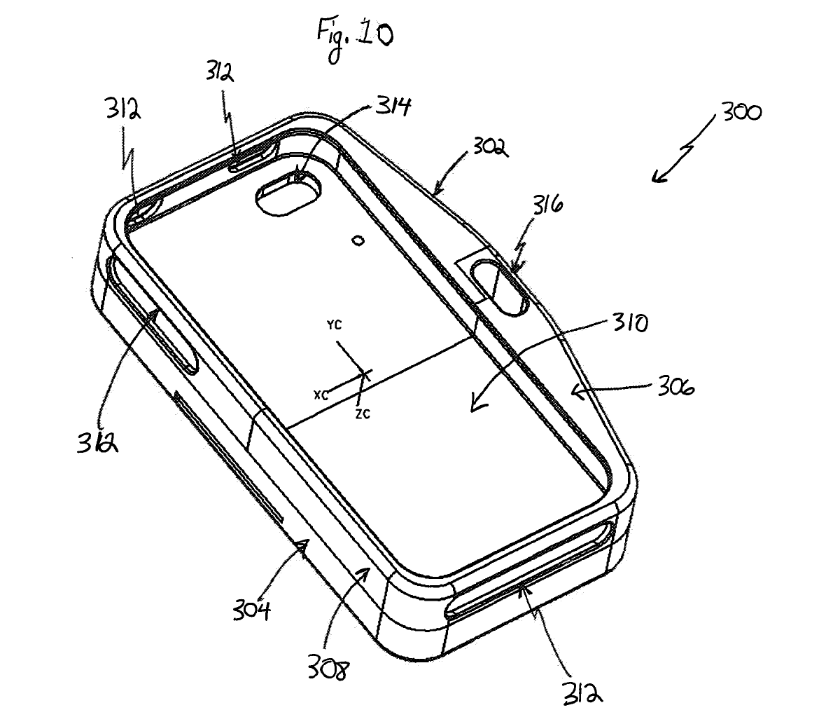

Referring now to FIGS. 10-12, another case representing another embodiment of the invention generally indicated by numeral 300. In the depicted embodiment, case 300 is able to function as a computer mouse and includes an upper portion 302 and lower portion 304. Upper portion 302 includes an upper surface 306 and a side wall 308. Side wall 308 defines a device receiving area 310. In the depicted embodiment, area 310 is configured to receive an iPhone, but in embodiments, area 310 may be configured to receive any suitable device such as a cellular phone from any manufacturer of any suitable tablet device. Referring still to FIG. 10, side wall 308 includes a plurality of openings each indicated by numeral 312. The openings 312 may be sized and arranged to allow a user to access buttons and switches resident upon the phone located within the area 310. It should be noted that the openings 312 may be positioned as needed to allow access to the phone's buttons and switches after the phone has been inserted into area 310. In the depicted embodiment, area 310 also includes an opening 314 positioned and located to correspond to the position of the camera location of the phone located within the area 310. Upper portion 302 also includes an aperture 316.

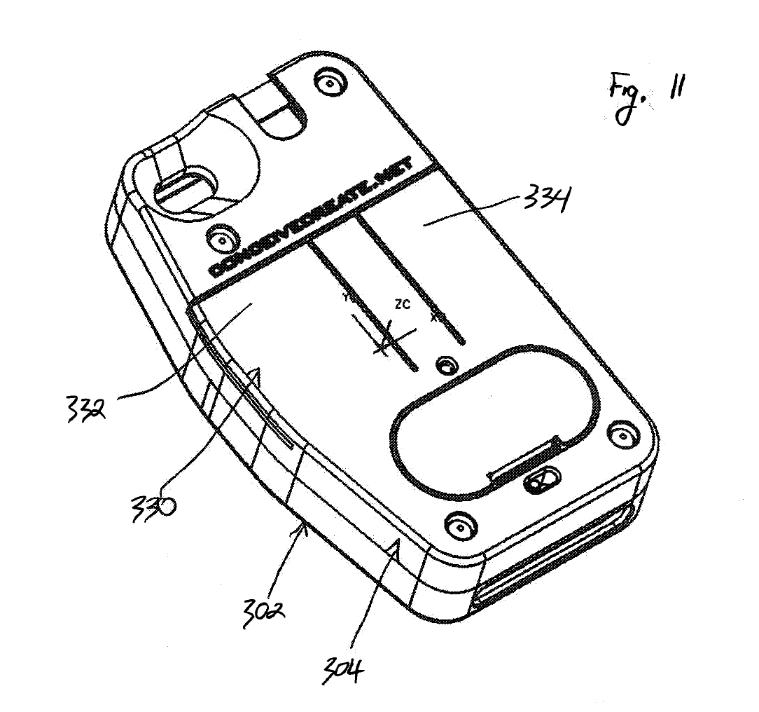

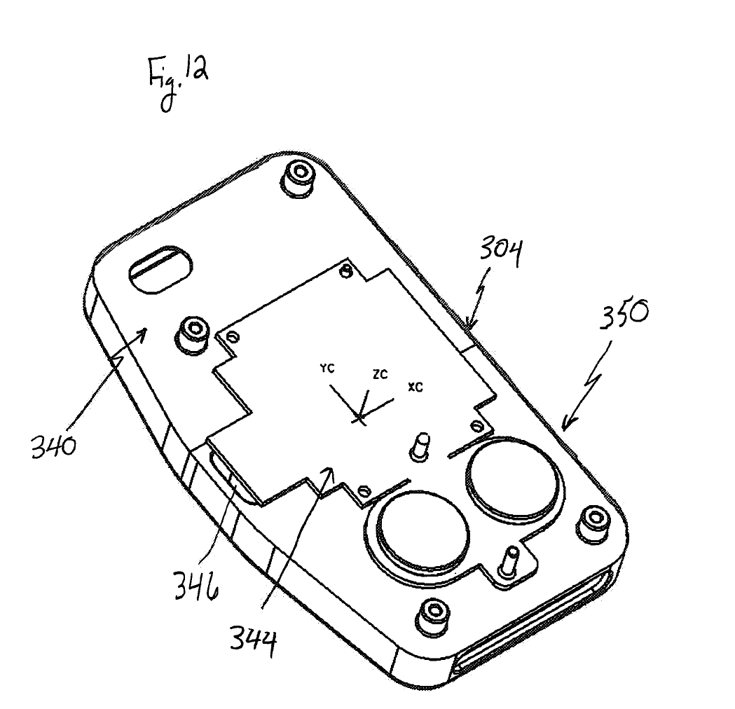

Referring now to FIGS. 11 and 12, lower portion 304 includes a back face indicated by 330. Back face 330 includes a first button 332 and a second button 334. The buttons 332, 334 are configured to be depressed by the finger of a user when the user holds the case 300 in a manner as a user would typically hold a mouse. In addition, the buttons 332, 334 are configured so that the buttons 332, 334 spring back to a neutral position once the button 332, 334 has been depressed and released by the user.

Referring specifically to FIG. 12, lower portion 304 includes a surface 340. Surface 340 includes a cavity (not shown). The cavity is sized and configured to receive a circuit board 344. Circuit board 344 includes an optical movement sensor 346 similar to that found in a standard mouse. The optical movement sensor 346 is configured to measure relative movement of the case relative to a table top (not shown) case 300 moves across the table.

Referring now to FIGS. 10-12, the upper portion 302 and lower portion 304 may be connected and joined in any suitable manner. For example, portion 302 may be connected to portion 304 by way of some known adhesive. In the depicted embodiment of case 300, optical movement sensor 346 is configured to extend through opening 316 of upper portion 302. Thus, when assembled, the case 300 may be used as a computer mouse, with the movement of the mouse being determined by laser projection portion 346 through opening 316. The “clicking” of the mouse can be achieved by the user depressing the buttons 332, 334. Due to the inclusion of a power source 350, the case 300 may be utilized as a mouse without the inclusion of a device in area 310. Furthermore, circuit board 344 may allow the case 300 to communicate with a computer wirelessly via any standard communication protocol, such as Bluetooth, WiFi or near field communication, for example.

The foregoing description of the embodiments has been provided for purposes of illustration and description. It is not intended to be exhaustive or to limit the disclosure. Individual elements or features of a particular embodiment are generally not limited to that particular embodiment; but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A case for an electronic device comprising:
a backside;
a sidewall extending from said backside, said sidewall defining a recess and said recess sized and configured to receive an electronic device;
a power source; and
a circuit connected to said power source, said circuit being capable of performing a function;
wherein said circuit is capable of performing the function regardless of whether the electronic device is located within said recess.

2. The case set forth in claim 1 wherein said power source is a battery.

3. The case set forth in claim 2 wherein said battery is a rechargeable battery.

4. The case set forth in claim 2 further comprising a cover connected to said backside and said cover is capable of being removed.

5. The case set forth in claim 4 wherein said cover is configured to cover at least a portion of said battery.

6. The case set forth in claim 5 wherein said battery is disposable.

7. The case set forth in claim 1 wherein said electronic device is a cellular phone.

8. The case set forth in claim 1 wherein said electronic device is a tablet computer.

9. The case set forth in claim 1 further comprising a first button and an optical movement sensor and the function of said circuit is a mouse.

10. The case set forth in claim 1 further comprising a second circuit capable of performing a second function.

11. The case set forth in claim 1 wherein said circuit is modular.

12. The case set forth in claim 11 wherein said backside further includes a backside recess and said circuit is removeably located within said backside recess.

13. A case for an electronic device comprising;
a sidewall defining a recess sized and configured to receive an electronic device;
a backside connected to said sidewall;
a power source located within said backside; and
a circuit modularly connected to said backside and electrically connected to said power source;
wherein said circuit is configured to perform a function.

14. The case set forth in claim 13 wherein said backside includes a recess configured to receive said circuit.

15. The case set forth in claim 13 further including a second circuit connected to said backside and electrically connected to said power source.

16. The case set forth in claim 15 wherein said first circuit and said second circuit communicate by way of near field communication.

17. The case set forth in claim 13 wherein said power source is removeable.

18. The case set forth in claim 13 wherein said power source is rechargeable.

19. The case set forth in claim 13 wherein said circuit communicates with said electronic device by way of a near field communication protocol.

20. The case set forth in claim 18 wherein said near field communication protocol is Bluetooth.

21. A case for an electronic device comprising:
a sidewall defining a recess configured to receive an electronic device;
a backside connected to said sidewall;
a power source; and
a circuit at least partially located within said backside and electrically connected to said power source;
wherein said circuit wirelessly connects to the electronic device.

22. The case set forth in claim 24 wherein the wireless communication between said circuit and said device is accomplished by way of a near field communication protocol.

23. The case set forth in claim 25 wherein said near field communication protocol is Bluetooth.

24. The case set forth in claim 24 further including a second circuit located within said backside and electrically connected to said power source.

25. The case set forth in claim 27 wherein said first circuit wirelessly communicates with said second circuit.

26. The case set forth in claim 28 wherein said first circuit is modularly connected said backside.

27. The case set forth in claim 29 wherein said backside includes a recess configured to receive said first circuit.

28. The case set forth in claim 30 wherein said first circuit is retained within said recess at least partially by way of a dovetail connection.

29. The case set forth in claim 31 wherein said electronic device is a cellular phone.

30. The case set forth in claim 31 wherein said electronic device is a tablet computer.
